(19) United States
(12) Patent Application Publication
(10) Pub. No.: US 2026/0147028 A1
(43) Pub. Date: May 28, 2026

(54) HIGH SPEED SERIAL PROTOCOL LOW FREQUENCY PERIODIC SIGNALING DETECTION

(71) Applicant: Xilinx, Inc., San Jose, CA (US)

(72) Inventors: John Bloomfield, San Jose, CA (US); Benjamin M. Fell, San Jose, CA (US)

(21) Appl. No.: 18/962,063

(22) Filed: Nov. 27, 2024

(51) Int. Cl. G01R 29/02; G01R 29/08

(52) U.S. Cl. CPC G01R 29/023; G01R 29/0892

(57) ABSTRACT

A detector for detecting a periodic square wave (PSW) includes: an interface circuit configured to generate a serial bit stream (SBS) by sampling an input signal carrying the PSW; a decimation encoder circuit (DEC) coupled to the interface circuit and configured to generate, for every first number of bits in the SBS, a symbol in a symbol stream; a pulse width estimator (PWE) configured to generate, for each symbol generated by the DEC, an estimate of a width of a most recent pulse (MRP) in a sequence of bits in the SBS, where the sequence of bits correspond to a pre-determined number of most recent symbols generated by the DEC; and a state machine coupled to the PWE and configured to declare detection of the PSW in response to detecting that the estimate of the width of the MRP is within a pre-determined range for a pre-determined period of time.

### TECHNICAL FIELD

The present invention relates generally to a detector for detecting a periodic square wave signal.

### BACKGROUND

Periodic square wave signals may be used for different signaling purposes. For example, in the DisplayPort (DP) standard, a Low Frequency Periodic Signal (LFPS), which is a periodic square wave signal having a frequency between 25 MHz and 40 MHz, is used to indicate that the transmitting device is leaving a power down state, and the receiving device should wake up. The receiving device includes a detector for detecting the LFPS, such that the receiving device can wake up from, e.g., a standby mode or a power down mode and get ready for receiving data. Conventional detectors for detecting periodic square wave signals may be complicated to implement, and may require large time delay before detection can be achieved. There is a need in the art for detectors that are simple to implement, yet can detect a periodic square wave signal quickly to improve the performance of the receiving device.

### SUMMARY

In accordance with an implementation, a detector for detecting a periodic square wave in a received signal includes: an interface circuit, wherein the interface circuit is configured to receive an input signal carrying the periodic square wave and sample the input signal at a sampling frequency to generate a serial bit stream; a decimation encoder circuit coupled to the interface circuit and configured to, based on the serial bit stream, generate a symbol stream having a symbol rate lower than the sampling frequency, wherein the decimation encoder circuit is configured to generate, for every first number of bits in the serial bit stream, a symbol in the symbol stream; a pulse width estimator coupled to the decimation encoder circuit and configured to generate, for each symbol generated by the decimation encoder circuit, an estimate of a width of a most recent pulse in a sequence of bits in the serial bit stream, wherein the sequence of bits correspond to a pre-determined number of most recent symbols generated by the decimation encoder circuit; and a state machine coupled to the pulse width estimator, wherein the state machine is configured to declare detection of the periodic square wave in response to detecting that the estimate of the width of the most recent pulse is within a pre-determined range for a pre-determined period of time.

In accordance with an implementation, a detector for detecting a Low Frequency Periodic Signal (LFPS) transmitted on a DisplayPort (DP) cable includes: a Serializer/Deserializer (SerDes) interface circuit, wherein the SerDes interface circuit is configured to sample a signal on the DP cable to generate a serial bit stream; a decimation encoder circuit coupled to the SerDes interface circuit and configured to generated a symbol stream by mapping every first number of bits in the serial bit stream into a symbol of the symbol stream, wherein the symbol has a multi-bit value; a pulse width estimator coupled to the decimation encoder circuit and configured to estimate a width of a most recent pulse in a sequence of bits in the serial bit stream, wherein the sequence of bits correspond to a pre-determined number of most recent symbols generated by the decimation encoder circuit; and a state machine coupled to the pulse width estimator, wherein the state machine is configured to declare detection of the LFPS in response to detecting that the width of the most recent pulse in the sequence of bits is within a pre-determined range for a pre-determined period of time.

In accordance with an implementation, a method of detecting a periodic square wave in a received signal includes: sampling, using an interface circuit, an input signal carrying the periodic square wave to generate a serial bit stream; generating, using a decimation encoder circuit coupled to the interface circuit, a symbol stream having a symbol rate lower than a bit rate of the serial bit stream, wherein the decimation encoder circuit maps every first number of bits in the serial bit stream into a symbol in the symbol stream; estimating, using a pulse width estimator coupled to the decimation encoder circuit, a width of a most recent pulse in a sequence of bits in the serial bit stream, wherein the sequence of bits correspond to a pre-determined number of most recent symbols generated by the decimation encoder circuit; and detecting, using a state machine coupled to the pulse width estimator, that the estimated width of the most recent pulse is within a pre-determined range for a pre-determined period of time.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a block diagram of a DisplayPort (DP) system, in an implementation;

FIG. 2 illustrates a block diagram of a detector for a periodic square wave signal, in an implementation;

FIG. 3 illustrates a look-up table (LUT) for implementing a Two-to-One decimation encoder of the detector of FIG. 2, in an implementation;

FIG. 4 illustrates example configurations of the optional Two-to-One decimation encoders of the detector of FIG. 2 at different sample rates, in an implementation;

FIGS. 5A, 5B, and 5C together illustrate an LUT for implementing a pulse width filter of the detector of FIG. 2, in an implementation;

FIG. 6 illustrates a state transition diagram of a state machine of the detector of FIG. 2, in an implementation; and

FIG. 7 illustrates a flow chart of a method of detecting a periodic square wave in a received signal, in some implementations.

### DETAILED DESCRIPTION OF ILLUSTRATIVE EXAMPLES

The making and using of the presently disclosed examples are discussed in detail below. It should be appreciated, however, that the present invention provides many applicable inventive concepts that can be embodied in a wide variety of specific contexts. The specific examples discussed are merely illustrative of specific ways to make and use the invention, and do not limit the scope of the invention. Throughout the discussion herein, unless otherwise specified, the same or similar reference numerals or labels in different figures refer to the same or similar component or signal.

The present disclosure will be described with respect to examples in a specific context, namely detecting a Low Frequency Periodic Signal (LFPS) in a DisplayPort (DP) system, with the understanding that the principle of the present disclosure is not limited to LFPS detection in a DP system, and instead, may be used for detecting other types of periodic square wave signals in other types of systems or standards.

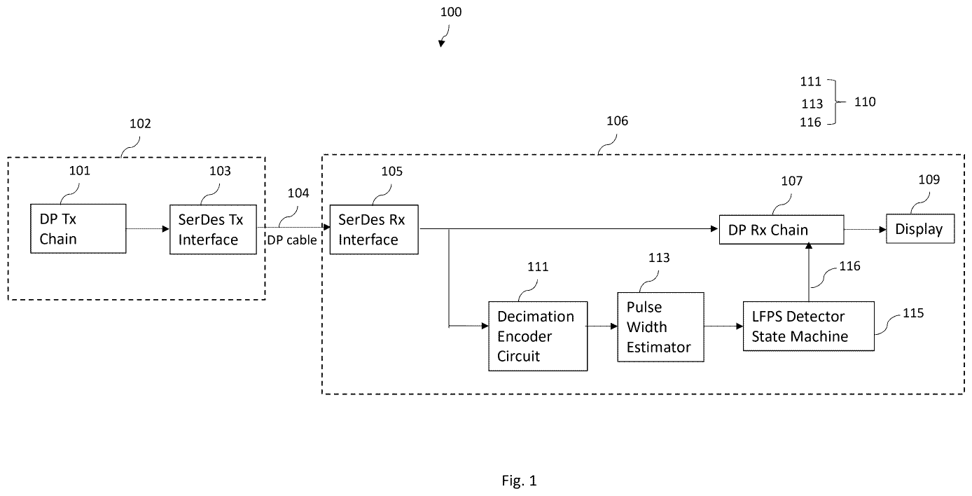

FIG. 1 illustrates a block diagram of a DisplayPort (DP) system 100, in an implementation. In the example of FIG. 1, the DP system includes a transmitter 102, a receiver 106, and a DP cable 104 connecting the transmitter 102 and the receiver 106. Note that for simplicity, not all features of the DP system 100 are illustrated.

As illustrated in FIG. 1, the transmitter 102 includes a DP transmit (Tx) chain 101 and a Serializer/Deserializer (SerDes) Tx interface circuit 103. The DP Tx chain 101 includes various processing blocks defined in the DP standard, such as processing blocks for packaging data (e.g., video data) and control signals into data packets, scrambling of the packet data, and encoding of the data (e.g., 8b/10b encoding in DP 1.x versions, or 128b/132b encoding in DP 2.0 and later) to ensure DC balance and provide enough transitions for clock recovery. The SerDes Tx interface circuit 103 performs parallel-to-serial conversion for the scrambled and encoded packet data, so that a serial bit stream (e.g., a one-bit data stream) is transmitted on the DP cable 104. The serial bit stream is transmitted as a differential signal on the DP cable 104, in some implementations. Note that in the DP standard, the DP cable 104 may support up to four parallel lanes, with each lane supporting a bit rate between 1 giga bits per second (Gbps) and 20 Gbps. For ease of discussion and without loss of generality, the discussion herein considers data transmitted on one of the lanes of the DP cable 104.

The receiver 106 includes a SerDes receive (Rx) interface circuit 105, a DP Rx chain 107, and optionally, a display 109 (e.g., a monitor). The display 109 may or may not be considered a part of the receiver 106. In addition, the receiver 106 includes a decimation encoder circuit 111, a pulse width estimator 113, and a state machine 115. As will be discussed in more details hereinafter, the decimation encoder circuit 111, the pulse width estimator 113, and the state machine 115 form a detector 110, which detector may also be referred to as a detector for periodic square wave signal, or a detector for LFPS.

In the illustrated implementation, the LFPS is a periodic square wave signal with a frequency between 25 MHz and 40 MHz. The periodic square wave signal (may also be referred to as a periodic square wave) is a digital waveform with alternating logic HIGH values (e.g., ones) and logic LOW values (e.g., zeros). A nominal duty cycle of the periodic square wave signal is 50%, in the illustrated implementation. The above frequency range for the LFPS is merely a non-limiting example. Skilled artisans will readily appreciate that the principle disclosed herein can be applied for periodic square wave signals having other frequencies.

In some implementations, the SerDes Rx interface circuit 105 includes a Clock and Data Recovery (CDR) module that recovers (e.g., extracts) a clock signal from the incoming data stream (e.g., the differential signal carrying the transmitted serial bit stream of the data packets), and uses the recovered clock signal to sample the signal on the DP cable 104 to generate a serial bit stream for processing by the receiver 106. For example, in the DP standard, the bit rate of the signal transmitted on the DP cable 104 carrying the data packets may be between 1 Gbps and 20 Gbps, and the CDR module recovers a clock signal with a frequency between 1 GHz and 20 GHz, and uses the recovered clock signal to sample the signal on the DP cable 104. CDR modules are known and used in the art, thus details are not discussed here. The SerDes Rx interface circuit 105 also performs serial-to-parallel conversion for the serial bit stream. The DP Rx chain 107 performs various receiver tasks defined in the DP standard, such as decoding (e.g., inverse operation of the 8b/10b encoding in DP 1.x versions, or 128b/132b encoding in DP 2.0 and later), descrambling, re-constructing the data packets, and processing of the data contained in the data packets. The processed data is then sent to the display 109.

During operation of the DP system, when the transmitter 102 is approaching the end of the data transmission, the transmitter 102 send a message in a data packet indicating that the data transmission is about to end. When the data transmission is completed, the transmitter 102 send another message in a data packet indicating that transmission is complete, and the transmitter 102 may then go into a power down state to save power. In response, the receiver 106 powers down the DP Rx chain 107 since no data is being transmitted by the transmitter 102. In some implementations, when the transmitter 102 needs to transmit data again, the transmitter 102 sends an LFPS to the receiver 106 to indicate that the transmitter 102 is leaving the power down state and that the receiver 106 (e.g., the DP Rx chain 107) should wake up in preparation for receiving data from the transmitter 102.

When the transmitter 102 is in the power down state, the CDR module of the SerDes Rx interface circuit 105 could no longer recover the clock signal embedded in the transmitted serial bit stream. In a reference DP system without the architecture and methods disclosed herein, the CDR of the SerDes Rx interface circuit 105 may only be able to recover the clock signal from the transmitted bit stream after the transmitter 102 starts data transmission again. However, such a frequency locking process may require that the CDR of the reference DP system constantly try to recover the clock signal (e.g., even when there is no transmitted bit stream), and/or may require that the SerDes Rx interface circuit 105 be reset periodically until the clock signal is recovered. However, the reset of the SerDes Rx interface circuit 105 may take a long time. In addition, after the reset, the CDR of the SerDes Rx interface circuit 105 may still need a long time to recover the clock signal from the transmitted data stream. The total time needed for the reference DP system to re-start data reception after the transmitter exits the power down state may be too long. The receiver 106 disclosed herein resolves the above issues and achieves quick recovery of clock signal after the transmitter 102 exits the power down state, details are discussed hereinafter.

In the illustrated implementation of FIG. 1, when the receiver 106 receives the message from the transmitter 102 indicating that the data transmission is about to end, the CDR of the SerDes Rx interface circuit 105 is frozen, meaning that the CDR of the SerDes Rx interface circuit 105 now generates a clock signal having the same frequency (e.g., a frequency between 1 GHz and 20 GHz) as the clock signal recovered from the incoming data stream. Note that the clock signal generated after the CDR of the SerDes Rx interface circuit 105 is frozen is a “free-running” clock signal, and the phase of this free-running clock signal may not be the optimal or near-optimal phase recovered from the incoming data stream. For example, the CDR of the SerDes Rx interface circuit 105 may include a Digital Phase-Locked Loop (DPLL) circuit for extracting the clock signal from the incoming data stream. When the CDR of the SerDes Rx interface circuit 105 is frozen, the adaptation of the DPLL is frozen, such that the DPLL generates the free-running clock signal with the same frequency as the recovered clock signal, but no longer adjusts the phase of the free-running clock signal. DPLL is known and used in the art, thus details are not discussed here. The CDR of the SerDes Rx interface circuit 105 keeps generating (e.g., maintains) the free-running clock signal after the transmitter 102 enters the power down state, and the free-running clock signal is used to sample the signal on the DP cable 104 to generate a serial bit stream for LPFS detection.

When the receiver 106 receives the message from the transmitter 102 indicating that the data transmission has ended, the receiver 106 powers down the DP Rx chain 107, and powers up the decimation encoder circuit 111, the pulse width estimator 113 and the state machine 115, such that the detector 110 starts working. In other words, the detector 110 starts searching for an LFPS in the serial bit stream generated by the SerDes Rx interface circuit 105 using the free-running clock. In an implementation, when the LFPS is detected, an output of the detector 110 (e.g., an output signal 116 of the state machine 115) goes high (e.g., having a value of one) and stays high as long as the LFPS is being detected. When the LFPS ends (which indicates that the transmitter 102 stopped transmitting the LFPS and is about to start transmitting data packets), the output of the detector 110 goes low (e.g., having a value of zero). The change from high to low in the output of the detector 110 is used as a trigger signal to “un-freeze” the CDR of the SerDes Rx interface circuit 105, meaning that the CDR of the SerDes Rx interface circuit 105 starts extracting clock signal from the incoming data steam again. For example, the DPLL in the CDR starts adaptation again to track the phase of the clock signal. Note that the frequency of the free-running clock is the same as the frequency of the clock signal embedded in the incoming data stream. Therefore, the CDR only needs to adjust the phase of the generated clock signal to lock on to the clock signal embedded in the incoming data stream. This results in a quick clock recovery after the transmitter 102 exits the power down state.

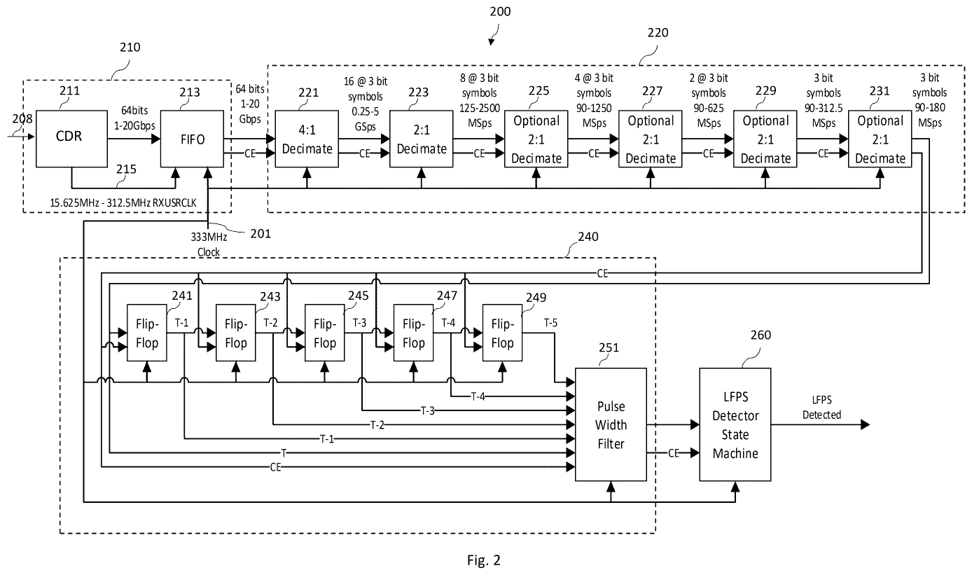

FIG. 2 illustrates a block diagram of a detector 200 for a periodic square wave signal, in an implementation. The detector 200 may be used as the detector 110 in FIG. 1. The detector 200 includes a decimation encoder circuit 220, a pulse width estimator 240, and a state machine 260, which correspond to the decimation encoder circuit 111, the pulse width estimator 113, and the state machine 115 in FIG. 1, respectively. FIG. 2 further illustrates an interface circuit 210 coupled to the detector 200. The interface circuit 210 corresponds to the SerDes Rx interface circuit 105 in FIG. 1, and is not part of the detector 200.

In the example of FIG. 2, the interface circuit 210 comprises a front-end module 211 and a First-In First-Out (FIFO) module 213 (also referred to as a FIFO memory block). The front-end module 211 includes a CDR module. The CDR module receives an input signal 208 carrying a transmitted serial bit stream having a bit rate between 1 Gbps and 20 Gbps, extracts a clock signal from the incoming data stream, and uses the clock signal to sample the input signal 208 to generate a serial bit stream (e.g., a one-bit data steam having a same bit rate as the transmitted serial bit stream) for reception. The front-end module 211 then sends a segment of the serial bit stream all at once to the FIFO module 213 using a clock signal 215, which clock signal 215 may be generated by the front-end module 211. In the illustrated example, the front-end module 211 performs a serial-to-parallel conversion for every 64 bits of the serial bit stream to generate a 64-bit wide data word, then sends the 64-bit data word to the FIFO module 213 at an active edge (e.g., a rising edge, or a falling edge) of the clock signal 215. Therefore, the frequency of the clock signal 215 is 1/64 of the bit rate F_{bit} (e.g., a fixed number between 1 Gbps and 20 Gbps) of the serial bit stream, and is within a frequency range between 15.625 MHz and 312.5 MHz, in the illustrated implementation.

As illustrated in FIG. 2, the data stored in the FIFO module 213 is read out by a clock signal 201 and sent to the decimation encoder circuit 220. In the illustrated implementation, the frequency of the clock signal 201 is 333 MHz, which is higher than the highest frequency (e.g., 312.5 MHz) of the clock signal 215. The faster read speed of the clock signal 201 ensures that the FIFO module 213 will not overflow. When the FIFO module 213 is not empty, for each active edge of the clock signal 201, a segment of bits (e.g., 64 consecutive bits) is outputted at a first output terminal of the FIFO module 213, and an enable signal (labeled as CE in FIG. 2) outputted at a second output terminal of the FIFO module 213 is asserted (e.g., have a logic HIGH value). When the FIFO module 213 is empty, no data is outputted at the first output terminal of the FIFO module 213 at the active edge of the clock signal 201, and the enable signal at the second output terminal of the FIFO module 213 is de-asserted (e.g., having a logic LOW value). Therefore, the enable signal CE generated by the FIFO module 213 is asserted at an average rate of F_{bit}/64. In the discussion herein, the terms “input terminal” and “output terminal,” which may also be referred to as “input port” and “output port”, may include one or more physical data lines (e.g., copper lines) such that one or more bits can be simultaneously received or transmitted though the input terminal or the output terminal.

The clock signal 201 and the enable signal allow downstream processing modules to run at a much lower clock frequency, which may reduce the complexity and power consumption of the detector 200. Note that although the clock signal 201 has a lower frequency than the bit rate of the serial bit stream, the total number of bits transferred per second to the detector 200 is still equal to the bit rate of the serial bit stream. Note that the use of FIFO module 213 and the clock signals 215 and 201 in the interface circuit 210 as illustrated in FIG. 2 is merely a non-limiting example. Other configurations and structures for the interface circuit 210 are also possible and are fully intended to be included within the scope of the present disclosure.

Still referring to FIG. 2, the decimation encoder circuit 220 includes a plurality of decimation encoders (e.g., 221, 223, 225, 227, 229, 231) coupled in series. The decimation encoders may also be referred to as decimators. In addition, the decimation encoder 221 is also referred to as a Four-to-One decimation encoder since it achieves a 4:1 rate reduction. The decimation encoder 223 is also referred to as a Two-to-One decimation encoder since it achieves a 2:1 rate reduction. The decimation encoders 225, 227, 229, and 231 are also referred to as optional Two-to-One decimation encoders since each of them is able to achieve a 2:1 rate reduction and the 2:1 rate reduction could be optionally by-passed. In other words, the optional Two-to-One decimation encoders 225, 227, 229, and 231 are reconfigurable, and can switch between a first operational mode (to perform the 2:1 rate reduction) and a second operational mode (to function as a serializer or a pass-through device). Details are discussed hereinafter.

In FIG. 2, each of the decimation encoders 221, 223, 225, 227, 229, and 231 has an input terminal for receiving input data, a first output terminal for outputting data, and a second output terminal for outputting an enable signal (labeled as CE in FIG. 2) generated by the decimation encoder. In addition, each of the decimation encoders has a clock terminal for receiving a clock signal, and has an enable terminal for receiving an enable signal. In the example of FIG. 2, the clock terminal of each of the decimation encoders is connected to the clock signal 201, and the enable terminal of each of the decimation encoders is connected to the enable signal generated by an upstream processing module.

In the illustrated implementation, when the decimation encoder 221 is enabled (e.g., the enable signal connected to the enable terminal is asserted) at an active edge of the clock signal 201, the decimation encoder 221 receives 64 bits all at once from the FIFO module 213. The decimation encoder 221 encodes (e.g., maps) every four bits of the 64 bits into a three-bit symbol (e.g., a symbol having a three-bit value), thus achieving a 4:1 rate reduction (e.g., achieves a decimation factor of 4) and generating 16 symbols from the 64 bits. For example, the first four bits of the 64 bits are mapped into a first symbol, and the next four bits of the 64 bits are mapped into a second symbol, and so on. In some implementations, the 16 symbols generated by the decimation encoder 221 are outputted at the first output terminal of the decimation encoder 221 all at once at an active edge of the clock signal 201, and the enable signal at the second output terminal of the decimation encoder 221 is asserted (e.g., having a logic HIGH) at the corresponding active edge of the clock signal 201 to indicate that the values at the first output terminal are valid and to enable processing of a downstream processing module (e.g., 223).

In the illustrated implementation, the number of bits sent to the decimation encoder 221 per second is in a range between 1 giga bits and 20 giga bits, and the number of symbols generated (e.g., outputted) by the decimation encoder 221 per second is in a range between 0.25 giga symbols and 5 giga symbols. Therefore, the decimation encoder 221 is said to accept a bit stream having a bit rate in a range between 1 Gbps and 20 Gbps, and to generate (e.g., output) a symbol stream having a symbol rate in a range between 0.25 GSps and 5 GSps, with the understanding that the bit stream is received in segment of 64 bits at all once, and the symbols are outputted in segment of 16 symbols at all once. The annotations in FIG. 2 before and after each decimation encoder (e.g., 221, 223, 225, 227, 229, or 231) show the ranges of the data rates (e.g., bit rate or symbol rate) for its input data and output data, as well as the sizes of the segments of input data and output data received/transmitted at all once (e.g., at an active edge of the clock signal 201).

In an implementation, the decimation encoder 221 encodes (e.g., maps) every four bits of the 64 bits into a three-bit symbol by using the following mapping rule. If all four bits are zeros, the three-bit symbol is assigned a value of 0b000, where the prefix “ob” indicates that the numbers after the prefix are binary bits. For ease of discussion, the binary value ob000 is also referred to as a symbolic value 0 that indicates all zeros in the four bits. If all four bits are ones, the three-bit symbol is assigned a value of ob011, which is also referred to as a symbolic value 1 that indicates all ones in the four bits. If there is a single transition of zero to one in the four bits, the three-bit symbol is assigned a value of ob001, which is also referred to as a symbolic value R that indicates one rising edge in the four bits. For example, if the four bits are ob01111, ob0011, or ob0001, then the three-bit symbol is assigned the symbolic value R. In the above notation (e.g., 0b0111) for the four bits, the leftmost bit is the earliest arriving bit of the four bits, and the rightmost bit is the latest arriving bit of the four bits. If there is a single transition of one to zero in the four bits, the three-bit symbol is assigned a value of ob010, which is also referred to as a symbolic value F that indicates one falling edge in the four bits. For example, if the four bits are 0b1000, 0b1100, or 0b1110, then the three-bit symbol is assigned the symbolic value F. If there is more than one transitions between zero and one (e.g., from zero to one, or from one to zero) in the four bits, then the three-bit symbol is assigned a value of 0b1xx, where x stands for a “don't care” bit. The value of 0b1xx is also referred to as a symbolic value N, which indicates that the four bits are contaminated by noise (thus not reliable) due to more than one transitions in the four bits. Examples of the four bits having more than one transitions between zero and one include 0b0101, 0b1010, 0b0110, 0b1001, or the like.

As will be discussed hereinafter, the duration of the four bits that corresponds to (e.g., mapped to) a three-bit symbol is less than half of a cycle of the LFPS. Therefore, within the duration of the four bits, there can be at most one transition between zero and one. In other words, there can be at most one edge (e.g., a falling edge, or a rising edge) within the duration of the four bits. If more than one transitions (or more than one edges) occur in the four bits, then the four bits are most likely contaminated (e.g., distorted) by noise (e.g. the four bits are a pattern that is not part of the LFPS signal that is to be detected). Note that the mapping between the four bits and the three-bit value of the symbol illustrated above is merely a non-limiting example, other ways of mapping are possible and are fully intended to be included within the scope of the present disclosure.

By mapping every four bits into a symbol, the decimation encoder 221 not only achieves a 4:1 rate reduction, but also encodes the shape of the incoming bit stream in the value of the 3-bit symbol. In other words, the 3-bit value of the symbol contains information regarding the shape of a digital waveform defined by the four binary bits. For example, a symbolic value of R for the symbol indicates a rising edge within the four binary bits corresponding to (e.g., mapped to) the symbol. Therefore, the 3-bit value provide a graphic representation of the incoming bit stream, which enables efficient implementation of the other decimation encoders (e.g., 223, 225, 227, 229, and 231) and the pulse width estimator 240, details are discussed hereinafter.

The decimation encoder 223 achieves a 2:1 rate reduction (e.g., achieves a decimation factor of 2) by encoding (e.g., mapping) every two input symbols generated by the decimation encoder 221 into one output symbol. In the illustrated implementation, when the decimation encoder 223 is enabled (e.g., the enable signal connected to the enable terminal is asserted) at an active edge of the clock signal 201, the decimation encoder 223 receives 16 symbols from the decimation encoder 221 at all once. The decimation encoder 223 encodes (e.g., maps) every two symbols of the 16 received symbols into a three-bit symbol, thus achieving a 2:1 rate reduction and generating 8 output symbols. For example, the first two symbols of the 16 symbols are mapped into a first symbol, and the next two symbols of the 16 symbols are mapped into a second symbol, and so on. The 8 symbols generated by the decimation encoder 223 are outputted all at once at the first output terminal of the decimation encoder 223 at an active edge of the clock signal 201, and the enable signal at the second output terminal of the decimation encoder 223 is asserted (e.g., having a logic HIGH) at the corresponding active edge of the clock signal 201 to indicate that the values at the first output terminal are valid and to enable processing of a downstream processing module (e.g., 225).

In some implementations, the decimation encoder 223 encodes (e.g., maps) every two input symbols of the segment of input symbols (e.g., the 16 received symbols) into a three-bit output symbol by using the following mapping rule. If the number of bits corresponding to (e.g., mapped to) the two input symbols are all zeros, then the output symbol is assigned the symbolic value of 0 (indicating all zeros). Note that for the decimation encoder 223, the number of bits corresponding to the two input symbols is 8, due to the 4:1 rate reduction of the decimation encoder 221. Therefore, the mapping rule may also be described as mapping between the 8 bits and the output symbol. If the number of bits (e.g., 8 bits) corresponding to the two input symbols are all ones, then the output symbol is assigned the symbolic value of 1 (indicating all ones). If the number of bits (e.g., 8 bits) corresponding to the two input symbols has a single transition of zero to one, the output symbol is assigned a symbolic value R (indicating a rising edge). If the number of bits (e.g., 8 bits) corresponding to the two input symbols has a single transition of one to zero, the output symbol is assigned a symbolic value F (indicating a falling edge). If there is more than one transitions between zero and one in the number of bits (e.g., 8 bits) corresponding to the two input symbols, then the output symbol is assigned the symbolic value N (indicating noise). This mapping rule is also used for each of the decimation encoders 225, 227, 229, and 2231 when the decimation encoder is working in the first operation mode to achieve 2:1 rate reduction.

Skilled artisans will readily appreciate that the mapping rule for the decimation encoder 223 is similar to that of the decimation encoder 221, in that the value of the output symbol is determined by the shape of the digital waveform defined by the number of bits (e.g., 8 bits) mapped into the output symbol. The shape of the digital waveform includes information such as, e.g., the number of edges, the types of edges (rising edge or falling edge), and whether the digital waveform has a constant value of zero or one. As will be explained hereinafter, the duration of each output symbol of the decimation encoder 221 (or 223, or 225, or 227, or 229, or 231) is less than half of a cycle of the LFPS. Therefore, at most one edge (a falling edge or a rising edge) can be observed in the bits mapped into one output symbol, if there is no noise in the received serial bit stream. If more than one edges are observed in the bits mapped into one output symbol, it indicates that the bits contain noise and therefore, are not reliable.

A simplistic way to implement the mapping rule for the decimation encoder 223 is to look at the values of the number of bits (e.g., 8 bits) corresponding to the two input symbols (or equivalently, corresponding to the output symbol), and apply the mapping rule above. However, for decimation encoders (e.g., 225, 227, 229, and 231) located at later stages of the decimation encoder circuit 220, the number of bits corresponding to an output symbol may increase quickly (exponentially due to the 2:1 rate reduction of each decimation encoder), and it may be cumbersome to check all the bits in the number of bits corresponding to an output symbol. A much more efficient implementation of the mapping rule is achieved by just looking at the 3-bit value of the two input symbols, as discussed below.

Since the value (e.g., the symbolic value) of each input symbol to the decimation encoder 223 already contain information regarding the shape of the digital waveform defined by the bits mapped into each input symbol, the mapping rule can be easily implemented based on the shapes indicated by the symbolic values of the two input symbols. In other words, the symbolic values of the two input symbols allow a quick re-construction of the shape of the digital waveform defined by the number of bits corresponding to the output symbol. For example, if both input symbols have symbolic values of 0 (indicating all zeros values), then the output symbol is assigned a symbolic value of 0, because the waveform has all zero values. As another example, if the first input symbol (e.g., the earlier arriving input symbol) has a symbolic value of 0, and the second input symbol has a symbolic value of R (indicating a rising edge), then the output symbol is assigned a symbolic value of R, because there is a single rising edge in the second input symbol. As yet another example, if the first input symbol has a symbolic value of R (indicating a rising edge), and the second input symbol has a symbolic value of F (indicating a falling edge), then the output symbol is assigned a symbolic value of N (indicating noisy data), because there are more than one transitions (e.g., more than one edges) between zero and one in the number of bits corresponding to the output symbol.

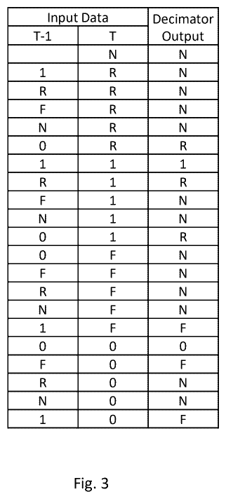

FIG. 3 illustrates a look-up table (LUT) for implementing the Two-to-One decimation encoder of the detector of FIG. 2, in an implementation. In particular, each row of the LUT in FIG. 2 illustrates the encoding (e.g., mapping) of two input symbols into one output symbol, and the LUT can be used to implement the mapping rule for the decimation encoders 223, 225, 227, 229, and 231. In FIG. 3, the first two columns are the two input symbols, with the first column showing the first (e.g., earlier arriving) input symbol, and the second column showing the second input symbol. The corresponding output symbol is shown in the third column. The values in the LUT of FIG. 3 are the symbolic values of the symbols. The empty cell in the first row of the LUT table means the value is “don't care.”

In FIG. 3, since each input symbol has a three-bit value, the mapping of the two input symbols into one output symbol can be implemented in hardware efficiently. For example, in Field Programmable Gate Array (FPGA) design, a 6-bit input LUT module is available, which can be used to implement the mapping rule of the LUT efficiently.

Referring back to FIG. 2, each of the optional Two-to-One decimation encoders 225, 227, 229, and 231 can be configured to work in a first operational mode or a second operation mode. The operation of the optional Two-to-One decimation encoders in each of the two operational modes is discussed below.

When working in the first operational mode, the 2:1 rate reduction function of the optional Two-to-One decimation encoder is enabled, and the optional Two-to-One decimation encoder is said to be “enabled.” For example, when enabled, the optional Two-to-One decimation encoders 225, 227, and 229 receive a segment of 8 input symbols, a segment of 4 input symbols, and a segment of 2 input symbols, respectively, all at once (e.g., at an active edge of the clock signal 201) from a respective upstream processing module, and encodes (e.g., maps) every two input symbols into one output symbol using the mapping rule illustrated in FIG. 3, thus achieving the 2:1 rate reduction. The output symbol(s) (referred to as a segment of output symbols) generated from the segment of input symbols are outputted all at once (e.g., at an active edge of the clock signal 201) at the first output terminal of the optional Two-to-One decimation encoder, and the enable signal at the second output terminal of the optional Two-to-One decimation encoder is asserted to indicate that the values at the second output terminal are valid and to enable a downstream processing module. In the illustrated implementation, the segments of the output symbols of the optional Two-to-One decimation encoders 225, 227, and 229 has 4 output symbols, 2 output symbols, and 1 output symbol, respectively.

The operation of the 2:1 rate reduction of the Two-to-One decimation encoder 231 is slightly different from that of the optional Two-to-One decimation encoders 225, 227, and 229, because the segment of input symbols received from the optional Two-to-One decimation encoder 229 only has one symbol. Therefore, the optional Two-to-One decimation encoder 231 generates one output symbol after receiving two input symbols at two different active edges of the clock signal 201. The enable signal generated by the optional Two-to-One decimation encoder 231 is asserted at a frequency that is half of the frequency of the enable signal received at its enable terminal. The output symbol stream generated by the optional Two-to-One decimation encoder 231 is also referred to as the output symbol stream of the decimation encoder circuit 220.

When working in the second operational mode, the 2:1 rate reduction function of the optional Two-to-One decimation encoder (e.g., 225, 227, 229, or 231) is by-passed, and the optional Two-to-One decimation encoder is said to be “bypassed.” The bypassed optional Two-to-One decimation encoders collectively function as a parallel-to-serial converter, such that the segment of output symbols (which may include 8, 4, or 2 output symbols) generated by the last enabled decimation decoder in the chain of decimation encoders are outputted serially (e.g., one symbol at a time) at the first output terminal of the optional Two-to-One decimation encoder 231. Details are discussed below.

In some implementations, when working in the second operational mode, the optional Two-to-One decimation encoders 225, 227, and 229 function as serializers. In particular, each of the optional Two-to-One decimation encoders 225, 227, and 229 splits the segment of input symbols into two equal sized groups (e.g., having the same number of output symbols), outputs each group of the output symbols at its first output terminal at all once (e.g., at an active edge of the clock signal 201), and asserts the enable signal at its second output terminal for each group of the output symbols. For example, after the optional Two-to-One decimation encoders 225 receives a segment of 8 input symbols, it outputs the first 4 input symbols all at once at an active edge of the clock signal 201, and then outputs the second 4 input symbols all at once at another (e.g., a subsequent) active edge of the clock signal 201. The enable signal are asserted twice, each with the outputting of a respective group of 4 symbols. In other words, when working in the second operational mode, the optional Two-to-One decimation encoder 225 (or 227, or 229) asserts its output enable signal at twice the frequency of the enable signal received at its enable terminal.

The operation of the optional Two-to-One decimation encoder 231 is different from that of the optional Two-to-One decimation encoder 225, 227, and 229 when working in the second operational mode. In particular, the optional Two-to-One decimation encoder 231 functions as a pass-through device, meaning that the input symbol at the input terminal and the enable signal at the enable terminal are sent directly to the first output terminal and second output terminal, respective.

In some implementations, the operational mode of the optional Two-to-One decimation encoders 225, 227, 229, and 231 are determined by the bit rate F_{bit} of the serial bit stream and a target range for the symbol rate of the output symbol stream at the output terminal (e.g., the first output terminal of the decimation encoder 231) of the decimation encoder circuit 220. An example criterion for selecting the target range for the symbol rate of the output symbol stream is described below.

Consider an example where the frequency of the LFPS is within a first frequency range R_{LFPS} between a lowest frequency F_{LFPS}_{_{LOW}} and a highest frequency F_{LFPS}_{_{HIGH}} (e.g., F_{LFPS}_{_{LOW}}≤R_{LFPS}≤F_{LFPS}_{_{HIGH}}), and the symbol rate of the output symbols is within a second frequency range R_{SYMBOL} between a lowest frequency R_{SYMBOL}_{_{LOW}} and a highest frequency R_{SYMBOL}_{_{HIGH}} (e.g., R_{SYMBOL}_{_{LOW}} ≤R_{SYMBOL}≤R_{SYMBOL}_{_{HIGH}}). The lowest frequency of the second frequency range R_{SYMBOL} is chosen to be greater than twice the highest frequency of the first frequency range RLFPS (e.g., 2<R_{SYMBOL}_{_{LOW}}/F_{LFPS}_{_{HIGH}}), and the highest frequency of the second frequency range R_{SYMBOL} is chosen to be smaller than eight times the lowest frequency of the first frequency range R_{LFPS} (e.g., R_{SYMBOL}_{_{HIGH}}/F_{LFPS}_{_{LOW}}<8). The above described criterion ensures that the slowest symbol rate (e.g., R_{SYMBOL}_{_{LOW}}) of the output symbol stream can still catch at least one “0” and at least one “1” in one cycle (e.g., one period) of the highest LPFS frequency (e.g., F_{LFPS}_{_{HIGH}}), and that that the fastest symbol rate (e.g., R_{SYMBOL}_{_{HIGH}}) of the output symbol stream can catch no more than four “0's” and no more than four “1's” in one cycle of the lowest LPFS frequency (e.g., F_{LFPS}_{_{LOW}}).

In the illustrated implementation, the bit rate F_{bit} of the serial bit stream generated by the interface circuit 210 is a known value between 1 Gbps and 20 Gbps, the frequency of the LPFS is unknown and is within a frequency range between 25 MHz and 40 MHz, and the target range for the symbol rate of the output symbol stream of the decimation encoder circuit 220 is chosen to be between 90 MHz and 180 MHz. This achieves a ratio of 2.25 between the lowest symbol rate R_{SYMBOL}_{_{LOW}} of the output symbol stream and the highest LFPS frequency F_{LFPS}_{_{HIGH}} (e.g., R_{SYMBOL}_{_{LOW}}/F_{LFPS}_{_{HIGH}}=¿2.25), and a ratio of 7.2 between the highest symbol rate R_{SYMBOL}_{_{HIGH}} of the output symbol stream and the lowest LFPS frequency F_{LFPS}_{_{LOW}} (e.g., R_{SYMBOL}_{_{HIGH}}/F_{LFPS}_{_{LOW}}=¿7.2). Skilled artisans will readily appreciate that the ranges, ratios, and numbers illustrated above are illustrative and non-limiting. The principle disclosed herein can be applied to systems with different data rates and/or frequency ranges.

Once the target range (e.g., between 90 MHz and 180 MHz) for the symbol rate of the output symbol stream is determined, the operational mode of the optional Two-to-One decimation encoders 225, 227, 229, and 231 are chosen accordingly to ensure that after all the rate reductions achieved by the decimation encoders, the symbol rate of the output symbol stream of the decimation encode circuit 220 is within the target range. One strategy of achieving the target range for the symbol rate is the following: given a bit rate F_{bit}, compute an output symbol rate F_{OUT}_{_{SYMBOL}}=F_{bit}/8 and check if F_{OUT}_{_{SYMBOL}} is within the target range (e.g., between 90 MHz and 180 MHz). If F_{OUT}_{_{SYMBOL}} is within the target range, all of the optional Two-to-One decimation encoders 225, 227, 229, and 231 are configured to work in the second operational mode (e.g., the 2:1 rate reduction operation is disabled). If F_{OUT}_{_{SYMBOL}} is not within the target range, the next optional Two-to-One decimation encoder (e.g., 225) is configured to work in the first operational mode (e.g., the 2:1 rate reduction operation is enabled), and the output symbol rate is updated as F_{OUT}_{_{SYMBOL}}=F_{OUT}_{_{SYMBOL}}/2. Next, check if the updated output symbol rate F_{OUT}_{_{SYMBOL}} is within the target range. If the updated F_{OUT}_{_{SYMBOL}} is within the target range, all of the remaining optional Two-to-One decimation encoders (e.g., 227, 229, and 231) are configured to work in the second operational mode (e.g., the 2:1 rate reduction operation is disabled). If the updated output symbol rate F_{OUT}_{_{SYMBOL}} is not within the target range, the next optional Two-to-One decimation encoder (e.g., 227) is configured to work in the first operational mode (e.g., the 2:1 rate reduction operation is enabled), and the output symbol rate is updated again as F_{OUT}_{_{SYMBOL}}=F_{OUT}_{_{SYMBOL}}/2. The above described process of checking the updated output symbol rate F_{OUT}_{_{SYMBOL}} and enabling the 2:1 rate reduction for the next optional Two-to-One decimation filter continues, until the updated output symbol rate F_{OUT}_{_{SYMBOL}} falls within the target range.

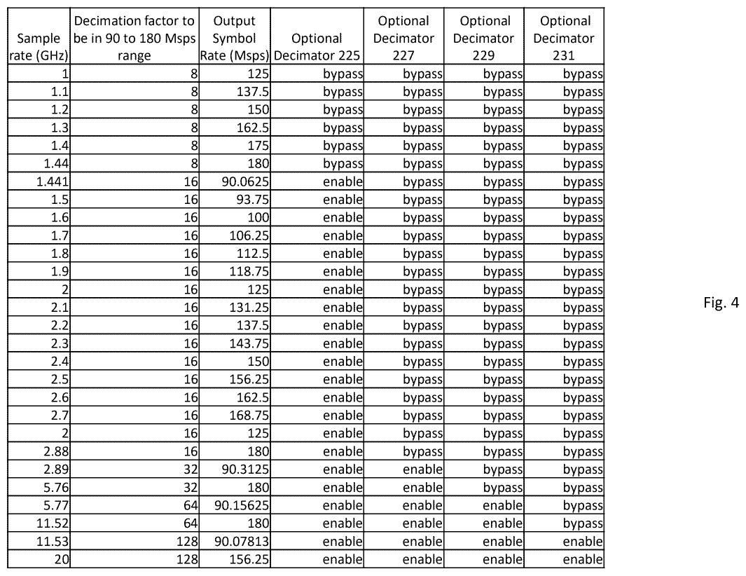

FIG. 4 illustrates example configurations of the optional Two-to-One decimation encoders of the detector 200 of FIG. 2 at different sample rates, in an implementation. Note that the sample rate here refers to the sampling frequency of the interface circuit 210, which is the same as the bit rates F_{bit} of the serial bit stream generated by the interface circuit 210.

In the table illustrated in FIG. 4, each row shows an example sample rate and the corresponding configurations for the optional Two-to-One decimation encoders. The first column lists different sample rates between 1 GHz and 20 GHz. The second column lists the corresponding total decimation factors needed to achieve the output symbol rates listed in the third column. The fourth, the fifth, the sixth, and the seventh columns list the corresponding configuration of the optional Two-to-One decimation encoders 225, 227, 229, and 231 respectively. In the table, “bypass” means that the corresponding optional Two-to-One decimation encoder is configured to work in the second operational mode (to bypass the 2:1 rate reduction function), and “enabled” means that the optional Two-to-One decimation encoder is configured to work in the first operational mode (to enable the 2:1 rate reduction function).

The configurations illustrated in FIG. 4 may be summarized by the following rule: if the sample rate is higher than 1.44 GHz, the optional Two-to-One decimation encoder 225 is enabled; otherwise it is bypassed. If the sample rate is higher than 2.88 GHz, the optional Two-to-One decimation encoder 227 is enabled; otherwise it is bypassed. If the sample rate is higher than 5.76 GHz, the optional Two-to-One decimation encoder 229 is enabled; otherwise it is bypassed. If the sample rate is higher than 11.52 GHz, the optional Two-to-One decimation encoder 231 is enabled; otherwise it is bypassed.

Note that the total decimation factors shown in the second column of the table in FIG. 4 are equal to the numbers of bits in the serial bit stream corresponding to (e.g., mapped to) an output symbol of the decimation encoder circuit 220, given the corresponding configurations of the optional Two-to-One decimation encoders 225, 227, 229, and 231. In other words, the numbers of bits in the serial bit stream corresponding to (e.g., mapped to) an output symbol of the decimation encoder circuit 220 is equal to the total decimation factor of the decimation encoder circuit 220. The total decimation factor may be calculated as a multiplication of the decimation factor of the decimation encoder 221, the decimation factor of the decimation encoder 223, and the decimation factors of the optional Two-to-One decimation encoders 225, 227, 229, and 231 that are working in the first operational mode. Denote the numbers of bits in the serial bit stream mapped to an output symbol of the decimation encoder circuit 220 as n, skilled artisans will readily appreciate that the decimation encoder circuit 220 maps every n bits in the serial bit stream into a three-bit output symbol, and the value (e.g., the symbolic value) of the three-bit output symbol contains information regarding the shape (e.g., the number and the type of edges in the n bits, etc.) of the digital waveform defined by the n bits in the serial bit stream.

The output of the decimation encoder circuit 220 is a symbol stream with a symbol rate within the target range (e.g., 90 MHz and 180 MHz). The enable signal generated by the optional Two-to-One decimation encoder 231 is asserted at the symbol rate to indicate that the value of the symbol at the first output terminal of the optional Two-to-One decimation encoder 231 is valid and to enable operation of the downstream processing module (e.g., 240). The symbol stream generated by the decimation encoder circuit 220 is sent to the pulse width estimator 240.

Referring back to FIG. 2, the pulse width estimator 240 comprises a shift register coupled to the decimation encoder circuit 220 and comprises a pulse width filter 251 coupled to the shift register. In the example of FIG. 2, the shift register is implemented as a plurality of D flip-flops, such as D flip-flops 241, 243, 245, 247, and 249, coupled in series. The clock terminals of the D flip-flops are connected to the clock signal 201. The enable terminals of the D flip-flops are connected to the enable signal generated by the decimation encoder 231. The input terminal of the first D flip-flop 241 is connected to the first output terminal of the decimation encoder 231. The input terminal of each of the downstream D flip-flops is connected to the output terminal of a respective upstream D flip-flop. Therefore, the shift register stores a pre-determined number (e.g., five) of previous output symbols generated by the decimation encoder circuit 220.

In the example of FIG. 2, the pulse width filter 251 receives six most recent output symbols generated by the decimation encoder circuit 220, which six most recent output symbols include the most recent output symbol and the five previous output symbols stored in the D flip-flops. The pulse width filter 251 then estimates the width of a most recent pulse in a sequence of bits in the serial bit stream corresponding to (e.g., mapped to) the six most recent output symbols. In some implementations, the most recent pulse is a positive pulse or a negative pulse in the sequence of bits, and is between a most recent falling edge in the sequence of bits and a most recent rising edge in the sequence of bits. In the example of FIG. 2, the sequence of bits has a total of 6n bits, where n is the number of bits (or equivalently the total decimation factor of the decimation encoder circuit 220) mapped into one output symbol of the decimation encoder circuit 220. In the illustrated implementation, the pulse width filter 251 is clocked by the clock signal 201 and is enabled by the enable signal generated by the decimation encoder 231. Therefore, for each new output symbol received from the decimation encoder 231, the pulse width filter 251 generates an estimate of the width of the most recent pulse (e.g., a positive pulse or a negative pulse) in the sequence of bits mapped to the six most recent output symbols, in the illustrated implementation.

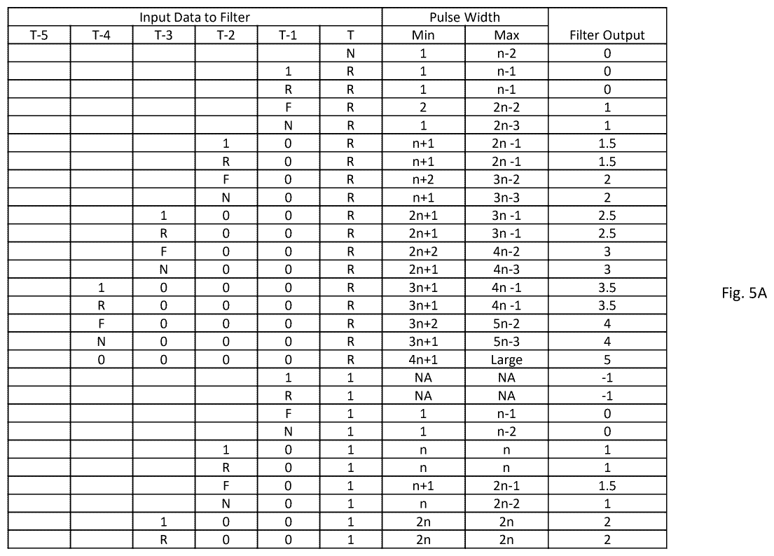

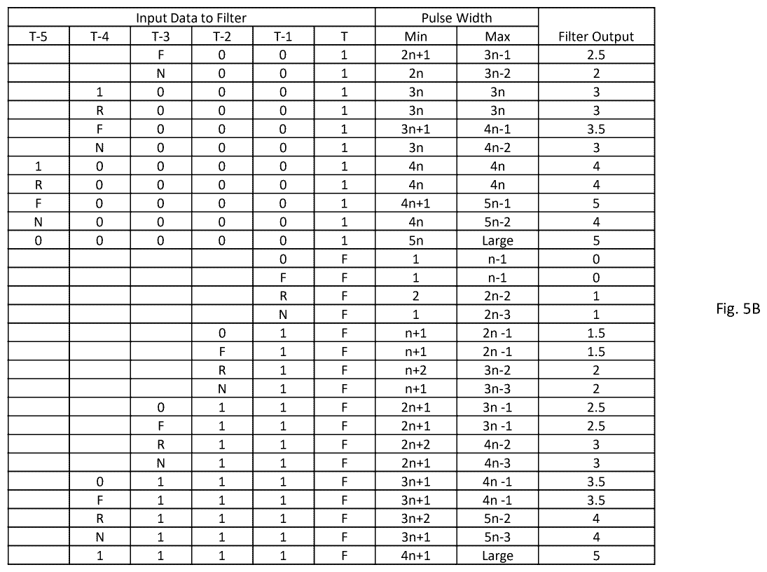

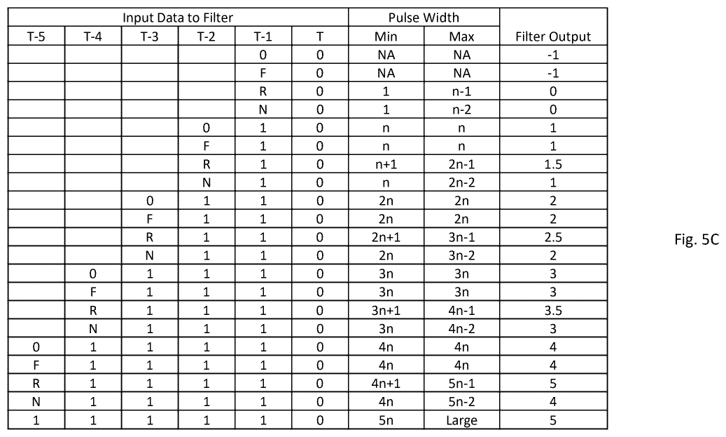

FIGS. 5A, 5B, and 5C together illustrate an LUT for implementing the pulse width filter 251 of FIG. 2, in an implementation. Each row in the LUT shows an example of the six most recent output symbols generated by the decimation encoder circuit 220, an estimate of the minimum width and the maximum width of the most recent pulse in a sequence of bits corresponding to the six most recent symbols, and the output value of the pulse width filter 251. Empty cells in the LUT means that the corresponding symbol values at those cells are “don't care.” In the LUT, the first six columns list the six most recent symbols, with the most recent symbol listed in the column with title “T” and the oldest symbol listed in the column with title “T-5.” The columns titled “Min” and “Max” list the estimated minimum widths and the estimated maximum widths of the most recent pulse in unit of bits. The number n in the estimated minimum (or maximum) widths represents the number of bits mapped into one output symbol of the decimation encoder circuit 220. The column with title “Filter Output” lists the output values of the pulse width filter 251 in units of n, where n is the number of bits mapped into one output symbol of the decimation encoder circuit 220. Note that the negative output value (e.g., −1) of the pulse width filter 251 is used to indicate that no pulse is detected yet.

The LUT in FIGS. 5A, 5B, and 5C illustrates an efficient way of estimating the width of the most recent pulse. Instead of estimating the width of the most recent pulse by looking at the 6n binary bits, the LUT only needs the values of the 6 most recent symbols (or less). Recall that the 3-bit value of a symbol contains information regarding the shape of the binary waveform defined by the n binary bits mapped into the symbol. The graphic information contained in the 3-bit value allows for a quick re-construction of the binary waveform defined by the 6n binary bits, which in turn allows the LUT in FIGS. 5A, 5B, and 5C to be constructed for efficient implementation.

Based on the frequency range (e.g., between 25 MHz and 40 MHz) of the LFPS, the range (e.g., between 90 MHz and 180 MHz) of the symbol rate for the output symbols generated by the decimation encoder circuit 220, and the number (e.g., 6) of most recent symbols used by the pulse width estimator 240 for estimating the pulse width, skilled artisan will readily appreciate that if the LFPS is present (e.g., being transmitted by the transmitter 102) and not corrupted by noise, the output value of the pulse width filter 251 should be within a pre-determined range. In the illustrated implementation, the pre-determined range R for the output values of the pulse width filter 251 is between 1 and 4 (e.g., 1≤R≤4). In other words, an output value of the pulse width filter 251 outside the pre-determined range Rindicates that no valid pulse has been detected, or no pulse has been detected yet. For example, an output value of zero from the pulse width filter 251 indicates that the pulse is too narrow to be a valid pulse from a LPFS, an output value of five from the pulse width filter 251 indicates that the pulse is too wide to be a valid pulse from LPFS, and an output value of-1 indicates that no pulse has been detected yet.

Referring back to FIG. 2, the value of the estimated pulse width is outputted at a first output terminal of the pulse width filter 251, and an enable signal (labeled as CE) is outputted at a second output terminal of the pulse width filter 251. The enable signal outputted by the pulse width filter 251 is asserted at the symbol rate, and is used to indicate that the values at the first output terminal is ready to be read and is used to enable the downstream processing module (e.g., 260).

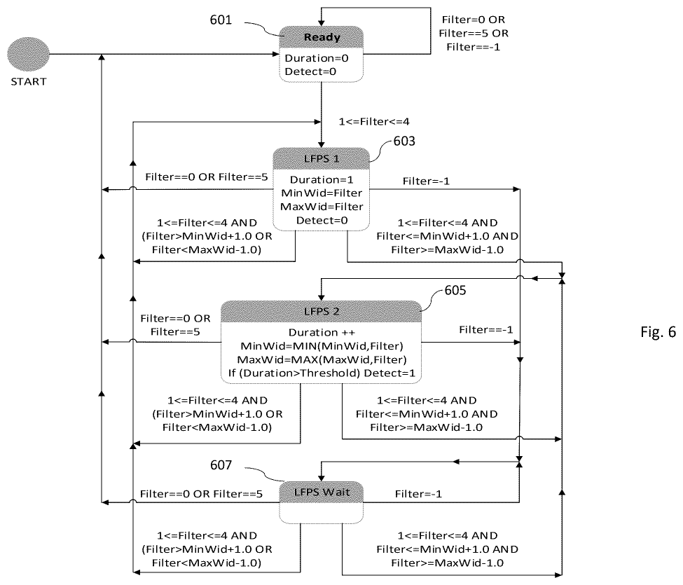

The output value of the pulse width estimator 240 is received by the state machine 260. The state machine 260 checks if the output value of the pulse width estimator 240 (e.g., the estimated pulse width) is a valid value (e.g., within the pre-determined range between 1 and 4). If the output value of the pulse width estimator 240 is a valid value, this indicates that the LPFS signal may be present. To prevent false detection, the state machine 260 checks the subsequent output values of the pulse width estimator 240. If a pre-determined number of consecutive output values of the pulse width estimator 240 are all valid values, and the most recent estimated pulse width is consistent with the previously estimated pulse widths, the state machine 260 declares that LPFS signal is detected. Details are discussed hereinafter with reference to the state transition diagram of the state machine 260 shown in FIG. 6.

FIG. 6 illustrates a state transition diagram of the state machine 260 of the detector 200 of FIG. 2, in an implementation. As illustrated in FIG. 6, after starting up (e.g., after a power up, or after a reset), the state machine 260 enters the state 601, which is referred to as a Ready State. Upon entering the Ready State, an LPFS detection flag, denoted as a variable Detect, is set to zero. A variable Duration, which counts the number of consecutive output values of the pulse width estimator 240 that are within the pre-determined range (e.g., between 1 and 4) and are consistent with the previously estimated pulse widths, is also set to zero.

In the Ready state, the state machine 260 checks the next output value from the pulse width estimator 240, which next output value is denoted as a variableFilter. If the value of the variable Filter is outside the pre-determined range, e.g., having a value of 0, 5, or −1, the state machine 260 stays in the Ready State. Otherwise, if the value of the variable Filter is within the pre-determined range (e.g., between 1 and 4), the state machine 260 transitions to the state 603, which is also referred to as LFPS1 State. Upon entering the LFPS1 State, the variable Duration is set to one. A variable MinWid, which tracks the minimum value of the variable Filter, is set to the current value of Filter. A variable MaxWid, which tracks the maximum value of the variable Filter, is also set to the current value of Filter.

In the LFPS1 state, the state machine 260 checks the next output value Filter from the pulse width estimator 240. If the output valueFilter is 0 or 5, the state machine 260 goes back to the Ready State. If the output valueFilter is −1 (which indicates that no pulse has been detected yet), the state machine 260 transitions to the state 607, also referred to as the LFPS Wait State. If the output valueFilter is between 1 and 4, and in addition, the output valueFilter is larger than MinWid+1 or smaller than MaxWid−1, the state machine 260 stays in the LFPS1 State. This is because the above condition suggests that the most recent output value Filter (e.g., the most recent estimated pulse width) deviates too much from the range of the previous output values Filter (e.g., the range of the previously estimated pulse widths), which may indicate that the previously estimated pulse widths and/or the currently estimated pulse width may be incorrect. For this reason, the state machine 260 stays in the LFPS1 State. If the output valueFilter is between 1 and 4, and in addition, the output valueFilter is between MinWid+1 and MaxWid−1 inclusive, the state machine 260 transitions to the state 605, also referred to as the LFPS2 State. This is because the above condition suggests that the most recent output value Filter (e.g., the most recent estimated pulse width) is consistent (e.g., is within ±1 of the range of previously estimated pulse widths) with the previous output values (e.g., the previously estimated pulse widths). As a result, the state machine 260 transitions to the LFPS2 State.

Upon entering the LFPS2 State, the variable Duration is incremented by one. The variable MinWid is updated with the lesser of the current output value Filter and the previous value of MinWid. Similarly, the variable MaxWid is updated with the greater of the current output value Filter and the previous value of MaxWid. If the updated variable Duration is greater than a pre-determined confidence level Threshold (e.g., a user assigned value), the variable Detect is assigned a value of one to indicate detection of LFPS.

In the LFPS2 State, the state machine 260 checks the next output value Filter from the pulse width estimator 240. If the output valueFilter is 0 or 5, the state machine 260 goes back to the Ready State. If the output valueFilter is −1, the state machine 260 transitions to the LFPS Wait State. If the output valueFilter is between 1 and 4, and in addition, the output valueFilter is larger than MinWid+1 or smaller than MaxWid−1, the state machine 260 goes to the LFPS1 State. If the output valueFilter is between 1 and 4, and in addition, the output valueFilter is between MinWid+1 and MaxWid−1 inclusive, the state machine 260 stays in the LFPS2 State, and variables Duration, MinWid, and MaxWid are updated in the same way as discussed above. If the updated variable Duration is greater than the pre-determined confidence level Threshold (e.g., a user assigned value), the variable Detect is assigned a value of one.

When the state machine 260 is in the LFPS Wait State, it checks the next output value Filter from the pulse width estimator 240. If the output valueFilter is 0 or 5, the state machine 260 goes back to the Ready State. If the output value Filter is −1, the state machine 260 stays in the LFPS Wait State. If the output value Filter is between 1 and 4, and in addition, the output valueFilter is larger than MinWid+1 or smaller than MaxWid−1, the state machine 260 goes to the LFPS1 State. If the output valueFilter is between 1 and 4, and in addition, the output valueFilter is between MinWid+1 and MaxWid−1 inclusive, the state machine 260 goes to the LFPS2 State.

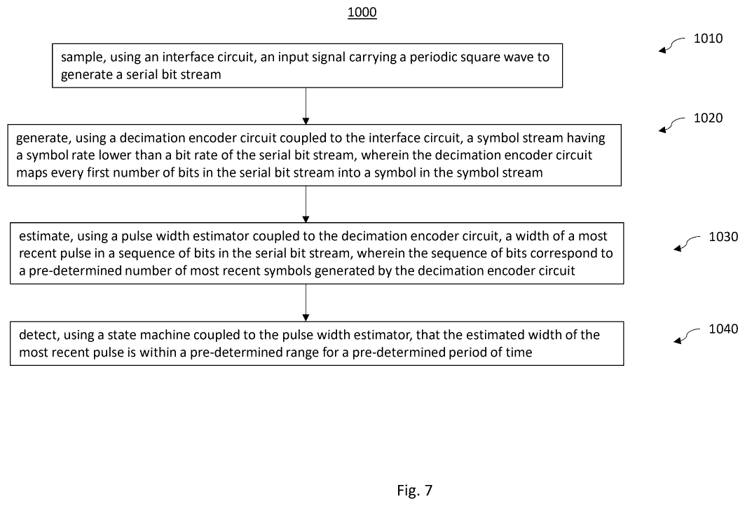

FIG. 7 illustrates a flow chart of a method of detecting a periodic square wave in a received signal, in some implementations. It should be understood that the example method shown in FIG. 7 is merely an example of many possible example methods. One of ordinary skill in the art would recognize many variations, alternatives, and modifications. For example, various steps as illustrated in FIG. 7 may be added, removed, replaced, rearranged, or repeated.

Referring to FIG. 7, at block 1010, an input signal carrying a periodic square wave is sampled using an interface circuit to generate a serial bit stream. At block 1020, a symbol stream having a symbol rate lower than a bit rate of the serial bit stream is generated using a decimation encoder circuit coupled to the interface circuit, wherein the decimation encoder circuit maps every first number of bits in the serial bit stream into a symbol in the symbol stream. At block 1030, a width of a most recent pulse in a sequence of bits in the serial bit stream is estimated using a pulse width estimator coupled to the decimation encoder circuit, wherein the sequence of bits correspond to a pre-determined number of most recent symbols generated by the decimation encoder circuit. At block 1040, a state machine coupled to the pulse width estimator detects that the estimated width of the most recent pulse is within a pre-determined range for a pre-determined period of time.

Implementations may achieve advantages as described below. For example, the disclosed receiver freezes the CDR of the interface circuit 210 before the transmission of data packets ends, and un-freezes the CDR at the end of the LFPS signal, e.g., before the transmitter starts transmission of data packets again. This allows a very quick clock recovery when the transmission of data packet begins, because the DPLL of the CDR only needs to recover the phase of the extracted clock signal. This drastically reduces the time needed by the receiver to get ready for data reception. The disclosed LFPS detector has a simple structure, runs on a much lower clock frequency than the bit rate of the serial bit stream, and allows for a very efficient hardware implementation. The disclosed LFPS detector supports a wide range of bit rate for the incoming serial bit stream and a wide range of frequency for the LFPS, thus providing improved flexibility to handle various input data rates. The disclosed LFPS detector allows for quick detection of the LFPS signal. A simple, low-cost hardware implementation with low power consumption is achieved by the disclosed LFPS detector.

Examples of the present invention are summarized here. Other examples can also be understood from the entirety of the specification and the claims filed herein.

Example 1. In accordance with an implementation, a detector for detecting a periodic square wave in a received signal includes: an interface circuit, wherein the interface circuit is configured to receive an input signal carrying the periodic square wave and sample the input signal at a sampling frequency to generate a serial bit stream; a decimation encoder circuit coupled to the interface circuit and configured to, based on the serial bit stream, generate a symbol stream having a symbol rate lower than the sampling frequency, wherein the decimation encoder circuit is configured to generate, for every first number of bits in the serial bit stream, a symbol in the symbol stream; a pulse width estimator coupled to the decimation encoder circuit and configured to generate, for each symbol generated by the decimation encoder circuit, an estimate of a width of a most recent pulse in a sequence of bits in the serial bit stream, wherein the sequence of bits correspond to a pre-determined number of most recent symbols generated by the decimation encoder circuit; and a state machine coupled to the pulse width estimator, wherein the state machine is configured to declare detection of the periodic square wave in response to detecting that the estimate of the width of the most recent pulse is within a pre-determined range for a pre-determined period of time.

Example 2. The detector of Example 1, wherein the symbol of the symbol stream has a multi-bit value, wherein the multi-bit value of the symbol contains information regarding a shape of a digital waveform defined by the first number of bits.

Example 3. The detector of Example 2, wherein the most recent pulse is a positive pulse or a negative pulse, and is between a most recent rising edge and a most recent falling edge in the sequence of bits.

Example 4. The detector of Example 2, wherein the sampling frequency has a first known value, and the periodic square wave has an unknown first frequency within a first pre-determined frequency range, wherein the symbol rate of the symbol stream has a unknown value within a second pre-determined frequency range, wherein a lowest frequency of the second pre-determined frequency range is greater than twice a highest frequency of the first pre-determined frequency range.

Example 5. The detector of Example 2, wherein the decimation encoder circuit comprises a Four-to-One decimation encoder coupled to the interface circuit, wherein the Four-to-One decimation encoder is configured to: receive a plurality of bits of the serial bit stream from the interface circuit at a first active edge of a clock signal; generate a first plurality of symbols by mapping every four bits of the plurality of bits into a symbol of the first plurality of symbols; and output the first plurality of symbols at a second active edge of the clock signal.

Example 6. The detector of Example 5, wherein mapping every four bits comprises: assigning a first value to the symbol of the first plurality of symbols when the four bits are zeros; assigning a second value to the symbol of the first plurality of symbols when the four bits are ones; assigning a third value to the symbol of the first plurality of symbols when there is a single transition from zero to one in the four bits; assigning a fourth value to the symbol of the first plurality of symbols when there is a single transition from one to zero in the four bits; and assigning a fifth value to the symbol of the first plurality of symbols when there are more than one transitions between zero and one in the four bits.

Example 7. The detector of Example 6, wherein the decimation encoder circuit further comprises a Two-to-One decimation encoder couple to an output terminal of the Four-to-One decimation encoder, wherein the Two-to-One decimation encoder is configured to: receive the first plurality of symbols at the second active edge of the clock signal; generate a second plurality of symbols by mapping every two symbols of the first plurality of symbols into a symbol of the second plurality of symbols; and output the second plurality of symbols at a third active edge of the clock signal.

Example 8. The detector of Example 7, wherein mapping every two symbols of the first plurality of symbols comprises: assigning the first value to the symbol of the second plurality of symbols when the two symbols of the first plurality of symbols have the first value; assigning the second value to the symbol of the second plurality of symbols when the two symbols of the first plurality of symbols have the second value; assigning the third value to the symbol of the second plurality of symbols when the two symbols of the first plurality of symbols indicate a single transition from zero to one in bits of the plurality of bits corresponding to the two symbols; assigning the fourth value to the symbol of the second plurality of symbols when the two symbols of the first plurality of symbols indicate a single transition from one to zero in the bits of the plurality of bits corresponding to the two symbols; and assigning the fifth value to the symbol of the second plurality of symbols when the two symbols of the first plurality of symbols indicate more than one transitions between zero and one in the bits of the plurality of bit corresponding to the two symbols.

Example 9. The detector of Example 8, wherein the decimation encoder circuit further comprises a plurality of optional Two-to-One decimation encoders coupled in series to an output terminal of the Two-to-One decimation encoder, wherein each of the plurality of optional Two-to-One decimation encoders is able to switch between a first operational mode and a second operational mode, and is configured to: achieve a 2:1 rate reduction by mapping every two input symbols into an output symbol when working in the first operational mode; and split a group of input symbols into two groups of symbols of equal size and output the two groups of symbols at two different active edges of the clock signal when working in the second operational mode.

Example 10. The detector of Example 1, wherein the pulse width estimator comprises: a shift register coupled to an output terminal of the decimation encoder circuit and configured to store a pre-determined number of previous symbols generated by the decimation encoder circuit; and a pulse width filter coupled to the shift register and configured to, based on a current symbol generated by the decimation encoder circuit and the pre-determined number of previous symbols stored in the shift register, estimate the width of the most recent pulse in the sequence of bits.

Example 11. In accordance with an implementation, a detector for detecting a Low Frequency Periodic Signal (LFPS) transmitted on a DisplayPort (DP) cable includes: a Serializer/Deserializer (SerDes) interface circuit, wherein the SerDes interface circuit is configured to sample a signal on the DP cable to generate a serial bit stream; a decimation encoder circuit coupled to the SerDes interface circuit and configured to generated a symbol stream by mapping every first number of bits in the serial bit stream into a symbol of the symbol stream, wherein the symbol has a multi-bit value; a pulse width estimator coupled to the decimation encoder circuit and configured to estimate a width of a most recent pulse in a sequence of bits in the serial bit stream, wherein the sequence of bits correspond to a pre-determined number of most recent symbols generated by the decimation encoder circuit; and a state machine coupled to the pulse width estimator, wherein the state machine is configured to declare detection of the LFPS in response to detecting that the width of the most recent pulse in the sequence of bits is within a pre-determined range for a pre-determined period of time.

Example 12. The detector of Example 11, wherein the decimation encoder circuit is configured to: assign a first value to the symbol when the first number of bits are zeros; assign a second value to the symbol when the first number of bits are ones; assign a third value to the symbol when there is a single transition from zero to one in the first number of bits; assign a fourth value to the symbol when there is a single transition from one to zero in the first number of bits; and assign a fifth value to the symbol when there are more than one transitions between zero and one in the first number of bits.

Example 13. The detector of Example 11, wherein the decimation encoder circuit comprises a plurality of decimation encoders coupled in series, wherein each of the decimation encoders is capable of achieving rate reduction by encoding multiple input data into an output data, where a first subset of the decimation encoders are reconfigurable and are capable of switching between a first operational mode and a second operational mode, wherein each of the first subset of decimation encoders is configured to achieve a 2:1 rate reduction in the first operational mode, and wherein the first subset of the decimation encoders are configured to collectively function as a parallel-to-serial converter when the first subset of decimation encoders are in the second operational mode.

Example 14. The detector of Example 13, wherein a bit rate of the serial bit stream is a known value, and a frequency of the LFPS is unknown and is within a first pre-determined frequency range, wherein a symbol rate of the symbol stream is unknown and is within a second pre-determined frequency range, wherein a lowest frequency of the second pre-determined frequency range is greater than twice a highest frequency of the first pre-determined frequency range.

Example 15. The detector of Example 14, wherein a ratio between the symbol rate and the frequency of the LFPS is between 2.25 and 7.2, the pre-determined number of most recent symbols has 6 symbols, and the pre-determined range is between 1 and 4.

Example 16. The detector of Example 15, wherein the bit rate has a value between 1 giga bits per second (Gbps) and 20 Gbps, the frequency of the LFPS is between 25 MHz and 40 MHz, and the symbol rate is between 90 million samples per second (MSps) and 180 MSps.

Example 17. The detector of Example 11, wherein the SerDes interface circuit comprises: a Clock and Data Recovery (CDR) circuit configured to extract a first clock signal from the signal on the DP cable and sample the signal using the first clock signal to generate the serial bit stream; and a First-In First-Out (FIFO) memory block coupled to the CDR circuit, wherein the SerDes interface circuit is configured to store segments of the serial bit stream into the FIFO memory block using a second clock signal, wherein a frequency of the second clock signal is lower than a frequency of the first clock signal.

Example 18. In accordance with an implementation, a method of detecting a periodic square wave in a received signal includes: sampling, using an interface circuit, an input signal carrying the periodic square wave to generate a serial bit stream; generating, using a decimation encoder circuit coupled to the interface circuit, a symbol stream having a symbol rate lower than a bit rate of the serial bit stream, wherein the decimation encoder circuit maps every first number of bits in the serial bit stream into a symbol in the symbol stream; generating, using a pulse width estimator coupled to the decimation encoder circuit, an estimated width of a most recent pulse in a sequence of bits in the serial bit stream, wherein the sequence of bits correspond to a pre-determined number of most recent symbols generated by the decimation encoder circuit; and detecting, using a state machine coupled to the pulse width estimator, that the estimated width of the most recent pulse is within a pre-determined range for a pre-determined period of time.

Example 19. The method of Example 18, wherein the symbol in the symbol stream has a multi-bit value, wherein the multi-bit value of the symbol contains information regarding a shape of a digital waveform defined by the first number of bits.

Example 20. The method of Example 19, wherein the pulse width estimator is configured to generate, for each symbol generated by the decimation encoder circuit, an estimate of the width of the most recent pulse in the sequence of bits.

While this invention has been described with reference to illustrative examples, this description is not intended to be construed in a limiting sense. Various modifications and combinations of the illustrative examples, as well as other examples of the invention, will be apparent to persons skilled in the art upon reference to the description. It is therefore intended that the appended claims encompass any such modifications or examples.

What is claimed is:

1. A detector for detecting a periodic square wave in a received signal, the detector comprising:
an interface circuit, wherein the interface circuit is configured to receive an input signal carrying the periodic square wave and sample the input signal at a sampling frequency to generate a serial bit stream;
a decimation encoder circuit coupled to the interface circuit and configured to, based on the serial bit stream, generate a symbol stream having a symbol rate lower than the sampling frequency, wherein the decimation encoder circuit is configured to generate, for every first number of bits in the serial bit stream, a symbol in the symbol stream;
a pulse width estimator coupled to the decimation encoder circuit and configured to generate, for each symbol generated by the decimation encoder circuit, an estimate of a width of a most recent pulse in a sequence of bits in the serial bit stream, wherein the sequence of bits correspond to a pre-determined number of most recent symbols generated by the decimation encoder circuit; and
a state machine coupled to the pulse width estimator, wherein the state machine is configured to declare detection of the periodic square wave in response to detecting that the estimate of the width of the most recent pulse is within a pre-determined range for a pre-determined period of time.

2. The detector of claim 1, wherein the symbol of the symbol stream has a multi-bit value, wherein the multi-bit value of the symbol contains information regarding a shape of a digital waveform defined by the first number of bits.

3. The detector of claim 2, wherein the most recent pulse is a positive pulse or a negative pulse, and is between a most recent rising edge and a most recent falling edge in the sequence of bits.

4. The detector of claim 2, wherein the sampling frequency has a first known value, and the periodic square wave has an unknown first frequency within a first pre-determined frequency range, wherein the symbol rate of the symbol stream has a unknown value within a second pre-determined frequency range, wherein a lowest frequency of the second pre-determined frequency range is greater than twice a highest frequency of the first pre-determined frequency range.

5. The detector of claim 2, wherein the decimation encoder circuit comprises a Four-to-One decimation encoder coupled to the interface circuit, wherein the Four-to-One decimation encoder is configured to:
receive a plurality of bits of the serial bit stream from the interface circuit at a first active edge of a clock signal;
generate a first plurality of symbols by mapping every four bits of the plurality of bits into a symbol of the first plurality of symbols; and
output the first plurality of symbols at a second active edge of the clock signal.

6. The detector of claim 5, wherein mapping every four bits comprises:
assigning a first value to the symbol of the first plurality of symbols when the four bits are zeros;
assigning a second value to the symbol of the first plurality of symbols when the four bits are ones;
assigning a third value to the symbol of the first plurality of symbols when there is a single transition from zero to one in the four bits;
assigning a fourth value to the symbol of the first plurality of symbols when there is a single transition from one to zero in the four bits; and
assigning a fifth value to the symbol of the first plurality of symbols when there are more than one transitions between zero and one in the four bits.

7. The detector of claim 6, wherein the decimation encoder circuit further comprises a Two-to-One decimation encoder couple to an output terminal of the Four-to-One decimation encoder, wherein the Two-to-One decimation encoder is configured to:
receive the first plurality of symbols at the second active edge of the clock signal;
generate a second plurality of symbols by mapping every two symbols of the first plurality of symbols into a symbol of the second plurality of symbols; and
output the second plurality of symbols at a third active edge of the clock signal.

8. The detector of claim 7, wherein mapping every two symbols of the first plurality of symbols comprises:
assigning the first value to the symbol of the second plurality of symbols when the two symbols of the first plurality of symbols have the first value;
assigning the second value to the symbol of the second plurality of symbols when the two symbols of the first plurality of symbols have the second value;
assigning the third value to the symbol of the second plurality of symbols when the two symbols of the first plurality of symbols indicate a single transition from zero to one in bits of the plurality of bits corresponding to the two symbols;
assigning the fourth value to the symbol of the second plurality of symbols when the two symbols of the first plurality of symbols indicate a single transition from one to zero in the bits of the plurality of bits corresponding to the two symbols; and
assigning the fifth value to the symbol of the second plurality of symbols when the two symbols of the first plurality of symbols indicate more than one transitions between zero and one in the bits of the plurality of bit corresponding to the two symbols.

9. The detector of claim 8, wherein the decimation encoder circuit further comprises a plurality of optional Two-to-One decimation encoders coupled in series to an output terminal of the Two-to-One decimation encoder, wherein each of the plurality of optional Two-to-One decimation encoders is able to switch between a first operational mode and a second operational mode, and is configured to:
achieve a 2:1 rate reduction by mapping every two input symbols into an output symbol when working in the first operational mode; and
split a group of input symbols into two groups of symbols of equal size and output the two groups of symbols at two different active edges of the clock signal when working in the second operational mode.

10. The detector of claim 1, wherein the pulse width estimator comprises:
a shift register coupled to an output terminal of the decimation encoder circuit and configured to store a pre-determined number of previous symbols generated by the decimation encoder circuit; and
a pulse width filter coupled to the shift register and configured to, based on a current symbol generated by the decimation encoder circuit and the pre-determined number of previous symbols stored in the shift register, estimate the width of the most recent pulse in the sequence of bits.

11. A detector for detecting a Low Frequency Periodic Signal (LFPS) transmitted on a DisplayPort (DP) cable, the detector comprising:
a Serializer/Deserializer (SerDes) interface circuit, wherein the SerDes interface circuit is configured to sample a signal on the DP cable to generate a serial bit stream;
a decimation encoder circuit coupled to the SerDes interface circuit and configured to generated a symbol stream by mapping every first number of bits in the serial bit stream into a symbol of the symbol stream, wherein the symbol has a multi-bit value;
a pulse width estimator coupled to the decimation encoder circuit and configured to estimate a width of a most recent pulse in a sequence of bits in the serial bit stream, wherein the sequence of bits correspond to a pre-determined number of most recent symbols generated by the decimation encoder circuit; and
a state machine coupled to the pulse width estimator, wherein the state machine is configured to declare detection of the LFPS in response to detecting that the width of the most recent pulse in the sequence of bits is within a pre-determined range for a pre-determined period of time.

12. The detector of claim 11, wherein the decimation encoder circuit is configured to:
assign a first value to the symbol when the first number of bits are zeros;
assign a second value to the symbol when the first number of bits are ones;
assign a third value to the symbol when there is a single transition from zero to one in the first number of bits;
assign a fourth value to the symbol when there is a single transition from one to zero in the first number of bits; and
assign a fifth value to the symbol when there are more than one transitions between zero and one in the first number of bits.

13. The detector of claim 11, wherein the decimation encoder circuit comprises a plurality of decimation encoders coupled in series, wherein each of the decimation encoders is capable of achieving rate reduction by encoding multiple input data into an output data, where a first subset of the decimation encoders are reconfigurable and are capable of switching between a first operational mode and a second operational mode, wherein each of the first subset of decimation encoders is configured to achieve a 2:1 rate reduction in the first operational mode, and wherein the first subset of the decimation encoders are configured to collectively function as a parallel-to-serial converter when the first subset of decimation encoders are in the second operational mode.

14. The detector of claim 13, wherein a bit rate of the serial bit stream is a known value, and a frequency of the LFPS is unknown and is within a first pre-determined frequency range, wherein a symbol rate of the symbol stream is unknown and is within a second pre-determined frequency range, wherein a lowest frequency of the second pre-determined frequency range is greater than twice a highest frequency of the first pre-determined frequency range.

15. The detector of claim 14, wherein a ratio between the symbol rate and the frequency of the LFPS is between 2.25 and 7.2, the pre-determined number of most recent symbols has 6 symbols, and the pre-determined range is between 1 and 4.

16. The detector of claim 15, wherein the bit rate has a value between 1 giga bits per second (Gbps) and 20 Gbps, the frequency of the LFPS is between 25 MHz and 40 MHz, and the symbol rate is between 90 million samples per second (MSps) and 180 MSps.

17. The detector of claim 11, wherein the SerDes interface circuit comprises:
a Clock and Data Recovery (CDR) circuit configured to extract a first clock signal from the signal on the DP cable and sample the signal using the first clock signal to generate the serial bit stream; and
a First-In First-Out (FIFO) memory block coupled to the CDR circuit, wherein the SerDes interface circuit is configured to store segments of the serial bit stream into the FIFO memory block using a second clock signal, wherein a frequency of the second clock signal is lower than a frequency of the first clock signal.

18. A method of detecting a periodic square wave in a received signal, the method comprising:
sampling, using an interface circuit, an input signal carrying the periodic square wave to generate a serial bit stream;
generating, using a decimation encoder circuit coupled to the interface circuit, a symbol stream having a symbol rate lower than a bit rate of the serial bit stream, wherein the decimation encoder circuit maps every first number of bits in the serial bit stream into a symbol in the symbol stream;
generating, using a pulse width estimator coupled to the decimation encoder circuit, an estimated width of a most recent pulse in a sequence of bits in the serial bit stream, wherein the sequence of bits correspond to a pre-determined number of most recent symbols generated by the decimation encoder circuit; and
detecting, using a state machine coupled to the pulse width estimator, that the estimated width of the most recent pulse is within a pre-determined range for a pre-determined period of time.

19. The method of claim 18, wherein the symbol in the symbol stream has a multi-bit value, wherein the multi-bit value of the symbol contains information regarding a shape of a digital waveform defined by the first number of bits.

20. The method of claim 19, wherein the pulse width estimator is configured to generate, for each symbol generated by the decimation encoder circuit, an estimate of the width of the most recent pulse in the sequence of bits.
